(19) United States
(12) Patent Application Publication
(10) Pub. No.: US 2026/0194573 A1
(43) Pub. Date: Jul. 9, 2026

(54) TEST APPARATUS AND SEMICONDUCTOR DEVICE TESTING METHOD

(71) Applicant: Samsung Electronics Co., Ltd., Suwon-si (KR)

(72) Inventor: CHUNGHYUN KIM, Suwon-si (KR)

(21) Appl. No.: 19/263,667

(22) Filed: Jul. 9, 2025

(30) Foreign Application Priority Data
Jan. 7, 2025 (KR) 10-2025-0002222

(51) Int. Cl. G01R 31/28

(52) U.S. Cl. CPC G01R 31/2891; G01R 31/2889

(57) ABSTRACT

Provided is a test apparatus including a probe card, a connecting ring spaced apart from the probe card, a first displacement sensor connected to a lower surface of the connecting ring, and ring connectors electrically connected to the connecting ring. The probe card includes a probe plate and probe connectors on the probe plate.

### CROSS-REFERENCE TO RELATED APPLICATIONS

This U.S. non-provisional patent application claims priority under 35 U.S.C. § 119 of Korean Patent Application No. 10-2025-0002222, filed on Jan. 7, 2025, the entire contents of which are hereby incorporated by reference.

### BACKGROUND

The present disclosure herein relates to a test apparatus and a semiconductor device testing method, and more particularly, to a test apparatus including a displacement sensor and a semiconductor device testing method using the displacement sensor.

After a plurality of semiconductor devices are formed on a wafer through semiconductor device manufacturing processes, tests of electrical properties are performed on each of the semiconductor devices. The tests of electrical properties may be performed by applying electrical signals to semiconductor devices on the wafer and reading signals output in response to the applied electrical signals. The applying and reading of electrical signals may be performed by a probe card that includes a plurality of probe pins.

The probe pin may be in contact with a pad or a bump on the wafer and transmit electrical signals. The probe pins may be of a needle type, a membrane type, an elastic pin type, or a spring pin type.

### SUMMARY

Aspects of the present disclosure provide a test apparatus having improved safety.

An embodiment of the inventive concept provides a test apparatus including: a probe card; a connecting plate spaced apart from the probe card; a first displacement sensor connected to a lower surface of the connecting plate; and interface connectors electrically connected to the connecting plate, wherein the probe card includes: a probe plate; and probe connectors on the probe plate.

In an embodiment of the inventive concept, a test apparatus includes: a probe plate; a stiffener on the probe plate; a probe connector on the probe plate; probe pins connected to the probe plate; a connecting plate spaced apart from the stiffener; and a displacement sensor overlapping the stiffener in a plan view, wherein the displacement sensor is disposed between the connecting plate and the stiffener in a plan view.

In an embodiment of the inventive concept, a semiconductor device testing method includes: testing a semiconductor device by using a probe card that includes a probe connector; decoupling an interface connector from the probe connector; and identifying a vertical position of the probe card by a first displacement sensor.

In an embodiment of the inventive concept, a test apparatus includes: a probe card including a plurality of first connectors; a tester; a plurality of second connectors electrically connected to the tester and configured to electrically and mechanically couple to the plurality of first connectors; a displacement sensor configured to identify a vertical position of the probe card; and a controller configured to determine whether the plurality of first connectors are coupled to or decoupled from the plurality of second connectors by using the vertical position.

In an embodiment of the inventive concept, a test apparatus comprises: a probe card including a plurality of first connectors; a tester; a plurality of second connectors electrically connected to the tester and configured to electrically and mechanically couple to the plurality of first connectors, respectively; a displacement sensor configured to identify a vertical position of the probe card; and a controller configured to determine whether at least one first connector of the plurality of first connectors is disconnected from at least one respective second connector of the plurality of second connectors by using the vertical position.

In an embodiment of the inventive concept, a test apparatus comprises: a probe card including a plurality of first connectors; a tester; a plurality of second connectors electrically connected to the tester and configured to electrically and mechanically couple to the plurality of first connectors, respectively; a displacement sensor configured to identify a vertical position of the probe card; and a controller configured to determine whether the probe card is disconnected from at least one second connector of the plurality of second connectors by using the vertical position.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a diagram showing a test apparatus according to some embodiments;

FIG. 2 is a diagram showing a connecting ring;

FIG. 3 is a diagram showing a probe card;

FIG. 4 is a cross-sectional view taken along line A1-A1′ of FIGS. 2 and 3;

FIG. 5 is a cross-sectional view taken along line A2-A2′ of FIGS. 2 and 3;

FIG. 6 is a diagram showing a probe connector and a ring connector;

FIG. 7 is a flowchart illustrating a semiconductor device testing method according to some embodiments; and

FIGS. 8, 9, and 10 are diagrams illustrating the semiconductor device testing method according to some embodiments.

### DETAILED DESCRIPTION

Hereinafter, embodiments of the inventive concept are described in detail with reference to the accompanying drawings. In this specification, the same reference numerals may refer to the same elements throughout.

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “CONNECTED” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

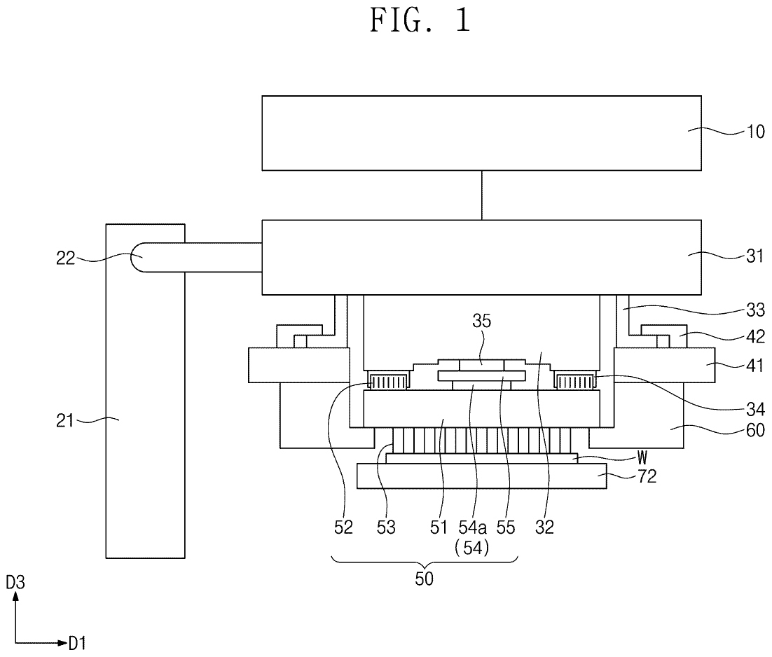

FIG. 1 is a diagram showing a test apparatus according to some embodiments.

Referring to FIG. 1, the test apparatus may include a tester 10, a support 21, a rotating arm 22, a test plate 31, a connecting ring 32, a first fixing part 33, a ring connector 34, a head plate 41, a second fixing part 42, a probe card 50, a card holder 60, and a stage 72.

A wafer W may be provided on the stage 72. A semiconductor device may be provided on the wafer W. The wafer W may include or be, for example, a semiconductor (e.g., silicon) wafer. The semiconductor device may include or be, for example, a semiconductor chip. The semiconductor chip may include or be, for example, a memory chip, a logic chip, a communication chip, or an image sensor chip.

The tester 10 may be electrically connected to the semiconductor device on the wafer W via the test plate 31, the connecting ring 32, the ring connector 34, and the probe card 50. The tester 10 may test the electrical properties of the semiconductor device. The tester 10 may transmit and receive an electrical signal to and from the semiconductor device.

The support 21 may be connected to the rotating arm 22. The rotating arm 22 may be connected to the test plate 31. The rotating arm 22 is rotatable. In some embodiments, the support 21 may include a drive unit for rotating the rotating arm 22.

The test plate 31 may be connected to the connecting ring 32 and the first fixing part 33. The connecting ring 32 and the first fixing part 33 may be connected to the lower surface of the test plate 31. The connecting ring 32 and the first fixing part 33 may be in contact with the lower surface of the test plate 31. The test plate 31 may include an electrical path through which an electrical signal passes. In some embodiments, the test plate 31 may include a shock-absorbing structure (e.g., a spring).

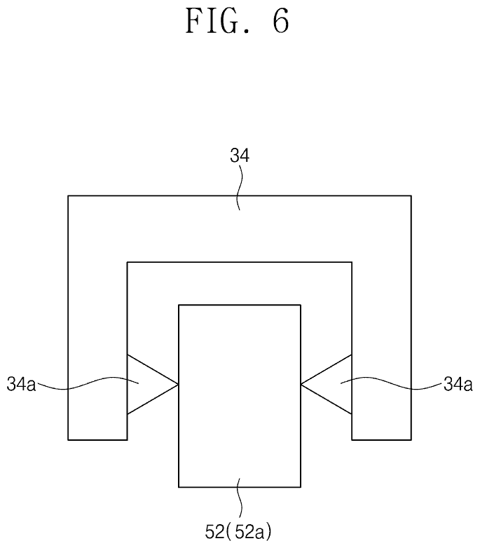

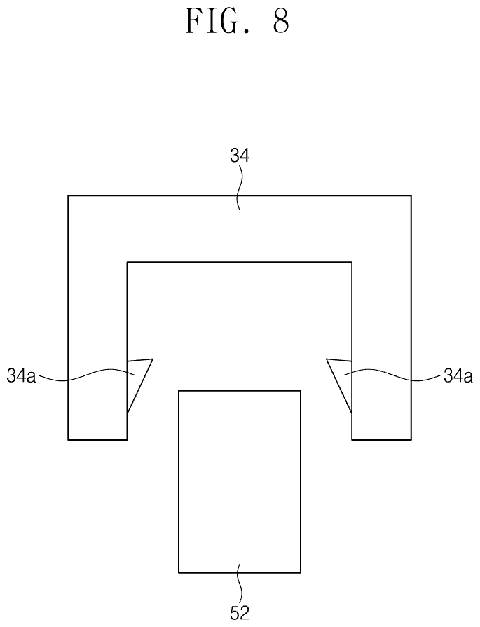

The connecting ring 32 may have a circular shape in a plan view. The connecting ring 32 may include an electrical path through which an electrical signal passes. The connecting ring (or connecting plate) 32 may be an interface circuit board which serves as an electrical interface between the tester 10 and the probe card 50. The interface circuit board 32 may have circuits to perform functions such as providing electrical connectivity between the test system (tester) 10 and the device under test (DUT) on a wafer (or package), transmitting and receiving test signals, adjusting and delivering test parameters such as voltage, current, and clock signals, and protecting the DUT and ensuring test reliability and signal quality. The connecting ring 32 may be a disk-shaped interface board, which is electrically connected to a plurality of interface connectors (ring connector) 34. The plurality of interface connectors 34 may be radially arranged with respect to the center of the interface circuit board 32 in a plan view. The plurality of interface connectors 34 may provide electrical connection between the probe card 50 and the interface circuit board 32. The plurality of interface connectors 34 may include a plurality of coupling portions 34a (which will be described with reference to FIGS. 6 and 8).

The first fixing part 33 may surround the connecting ring 32. The first fixing part 33 may be coupled to and decoupled from the second fixing part 42. In some embodiments, the first fixing part 33 and the second fixing part 42 may have a ring shape in a plan view.

The head plate 41 may surround the connecting ring 32. The second fixing part 42 may be connected onto the head plate 41. The second fixing part 42 may be connected to the upper surface of the head plate 41. The second fixing part 42 may be in contact with the upper surface of the head plate 41. The first fixing part 33 and the second fixing part 42 may be disposed between the head plate 41 and the test plate 31.

Ring connectors 34 may be connected to the connecting ring 32. The ring connectors 34 may be connected to the lower surface of the connecting ring 32. The ring connectors 34 may be in contact with the lower surface of the connecting ring 32. The ring connector 34 may include an electrical path through which an electrical signal passes. The ring connector 34 may include an inner space into which at least a portion of the probe connector 52 is inserted.

A clamp 35 may be connected to the connecting ring 32. The clamp 35 may be connected to the lower surface of the connecting ring 32. The clamp 35 may be in contact with the lower surface of the connecting ring 32. The clamp 35 may be coupled to and decoupled from a cover 55 of the probe card 50.

The card holder 60 may surround the probe card 50. The card holder 60 may support the probe card 50. The card holder 60 may move up and down. The head plate 41 and the connecting ring 32 may be disposed between the test plate 31 and the card holder 60.

The probe card 50 may include a probe plate 51, probe connectors 52, probe pins 53, a stiffener 54, and a cover 55.

The probe plate 51 may include an electrical path through which an electrical signal passes. The probe plate 51 may include, for example, a printed circuit board. The probe plate 51 may be supported by the card holder 60.

The probe connectors 52 may be connected onto the probe plate 51. The probe connectors 52 may be connected to the upper surface of the probe plate 51. The probe connectors 52 may be in contact with the upper surface of the probe plate 51. The probe connector 52 may include an electrical path through which an electrical signal passes. At least a portion of the probe connector 52 may be inserted into the inner space of the ring connector 34. The probe connector 52 may be coupled to and decoupled from the ring connector 34.

The stiffener 54 may be connected onto the probe plate 51. The stiffener 54 may be connected to the upper surface of the probe plate 51. The stiffener 54 may be in contact with the upper surface of the probe plate 51. The stiffener 54 may be a mechanical support structure attached to the probe plate 51 to prevent bending, maintain alignment accuracy, and ensure mechanical stability during probing and signal transmission. The stiffener 54 may be made of, for example, aluminum due to its excellent thermal conductivity and high rigidity.

The cover 55 may be connected onto the stiffener 54. The cover 55 may be connected to the upper surface of the stiffener 54. The cover 55 may be in contact with the upper surface of the stiffener 54. The cover 55 may be coupled to the clamp 35 and in contact with the lower surface of the clamp 35.

The probe pins 53 may be connected to the lower surface of the probe plate 51. The probe pins 53 may be in contact with the lower surface of the probe plate 51. A probe pin 53 may come into contact with a semiconductor device on the wafer W. The probe pin 53 may come into contact with, for example, a pad or a bump of the semiconductor device. The probe pin 53 may include a conductive material.

The tester 10, the test plate 31, the connecting ring 32, the ring connectors 34, the probe connectors 52, the probe plate 51, and the probe pins 53 may be electrically connected to each other.

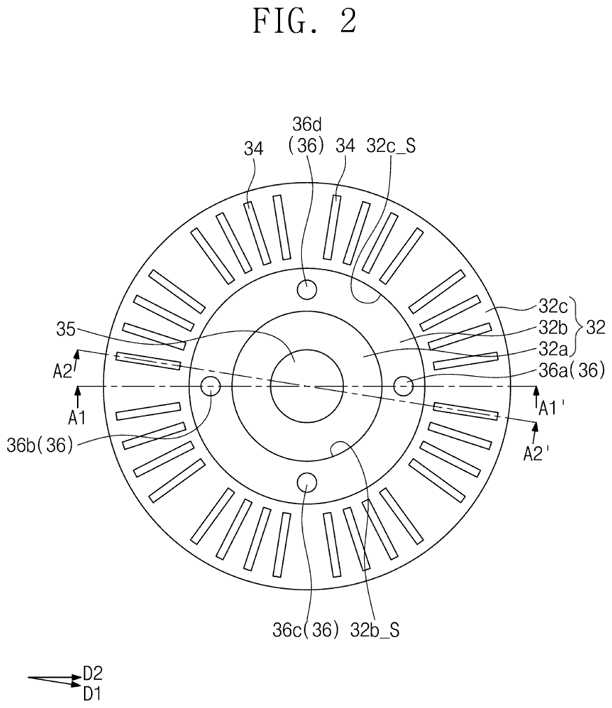

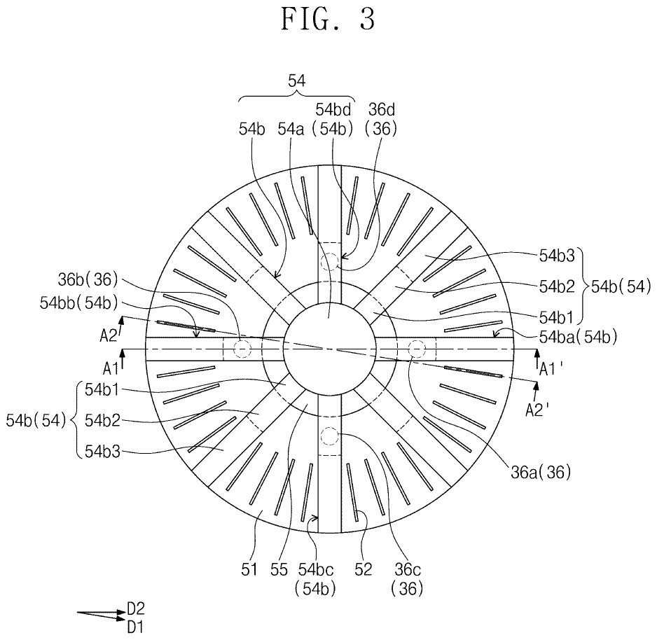

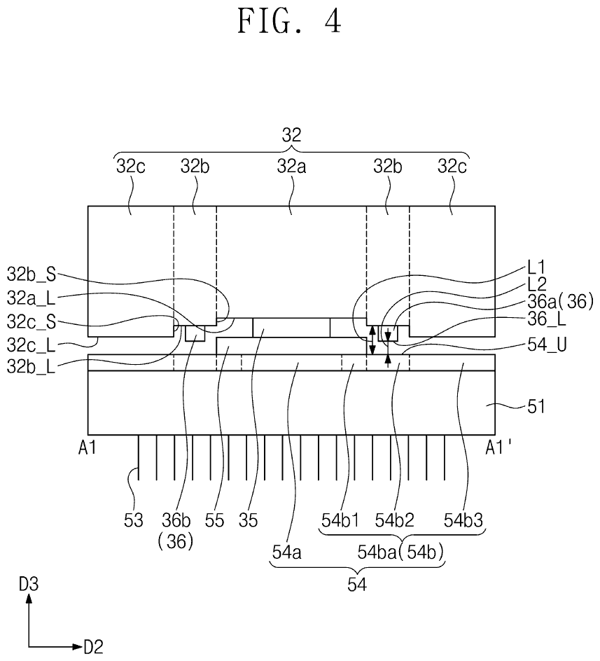

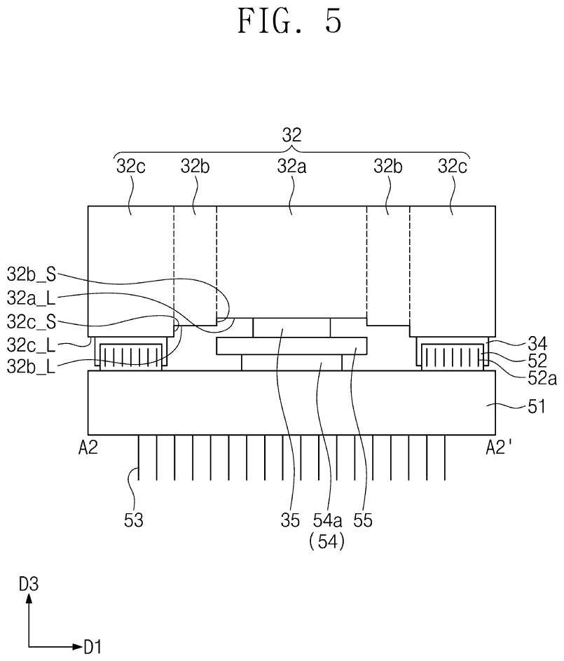

FIG. 2 is a diagram showing the connecting ring 32. FIG. 3 is a diagram showing the probe card 50. FIG. 4 is a cross-sectional view taken along line A1-A1′ of FIGS. 2 and 3. FIG. 5 is a cross-sectional view taken along line A2-A2′ of FIGS. 2 and 3.

Referring to FIGS. 2, 3, 4 and 5, the connecting ring 32 may have a ring (or circular or disc) shape in a plan view parallel to a first direction D1 and a second direction D2. The first direction D1 may intersect the second direction D2. The first direction D1 and the second direction D2 may represent, for example, horizontal directions.

The connecting ring 32 may include a first connecting section 32a, a second connecting section 32b surrounding the first connecting section 32a, and a third connecting section 32c surrounding the second connecting section 32b. Although the first connecting section 32a, the second connecting section 32b, and the third connecting section 32c are described separately, the first connecting section 32a, the second connecting section 32b, and the third connecting section 32c may be connected to each other without any boundaries to form a single structure.

The lower surface of the connecting ring 32 may include a lower surface 32a_L of the first connecting section 32a, a lower surface 32b_L of the second connecting section 32b, and a lower surface 32c_L of the third connecting section 32c. The level of the lower surface 32b_L of the second connecting section 32b may be lower than the level of the lower surface 32a_L of the first connecting section 32a. A distance L1 in a third direction D3 between the lower surface 32b_L of the second connecting section 32b and an upper surface 54_U of the stiffener 54 may be less than the distance in the third direction D3 between the lower surface 32a_L of the first connecting section 32a and the upper surface 54_U of the stiffener 54. The level of the lower surface 32c_L of the third connecting section 32c may be lower than the level of the lower surface 32b_L of the second connecting section 32b. The distance in the third direction D3 between the lower surface 32c_L of the third connecting section 32c and the upper surface 54_U of the stiffener 54 may be less than the distance L1 in the third direction D3 between the lower surface 32b_L of the second connecting section 32b and the upper surface 54_U of the stiffener 54. The distance L1 in the third direction D3 between the lower surface 32b_L of the second connecting section 32b and the upper surface 54_U of the stiffener 54 may be, for example, about 2.7 mm. For example, the distance L1 may be 2.7 mm with a tolerance of +10%.

The third direction D3 may intersect the first direction D1 and the second direction D2. For example, the third direction D3 may represent a vertical direction perpendicular to both the first direction D1 and the second direction D2.

The second connecting section 32b may include an inner side surface 32b_S that connects the lower surface 32b_L of the second connecting section 32b to the lower surface 32a_L of the first connecting section 32a. The third connecting section 32c may include an inner side surface 32c_S that connects the lower surface 32c_L of the third connecting section 32c to the lower surface 32b_L of the second connecting section 32b.

The probe card 50 may be spaced apart from (or partially connected to) the connecting ring 32 in the third direction D3. The test apparatus may further include displacement sensors 36 which are disposed between the connecting ring 32 and the probe card 50. The clamp 35 and the ring connectors 34 may be disposed between the probe card 50 and the connecting ring 32. The probe card 50 may be connected to the connecting ring 32 through the clamp 35 and/or the ring connector 34 in a detachable manner.

The probe plate 51 may be spaced apart from the connecting ring 32 in the third direction D3. The probe connectors 52, the stiffener 54, the cover 55, the clamp 35, the displacement sensors 36, and the ring connectors 34 may be disposed between the probe plate 51 and the connecting ring 32.

The stiffener 54 and the cover 55 may be spaced apart from the connecting ring 32 in the third direction D3. The stiffener 54 and the cover 55 may be spaced apart from a displacement sensor 36 in the second direction D2 and the third direction D3, respectively. The displacement sensor 36 may be disposed between the stiffener 54 and the connecting ring 32.

The displacement sensors 36 may include a first displacement sensor 36a, a second displacement sensor 36b, a third displacement sensor 36c, and a fourth displacement sensor 36d. The first and second displacement sensors 36a and 36b may be spaced apart from each other with the cover 55 and the clamp 35 therebetween. The third and fourth displacement sensors 36c and 36d may be spaced apart from each other with the cover 55 and the clamp 35 therebetween.

The first to fourth displacement sensors 36a, 36b, 36c, and 36d may be connected to the lower surface 32b_L of the second connecting section 32b. The first to fourth displacement sensors 36a, 36b, 36c, and 36d may be in contact with the lower surface 32b_L of the second connecting section 32b. The first to fourth displacement sensors 36a, 36b, 36c, and 36d may be surrounded by the third connecting section 32c in a plan view. The first to fourth displacement sensors 36a, 36b, 36c, and 36d may be surrounded by the inner side surface 32c_S of the third connecting section 32c. The first to fourth displacement sensors 36a, 36b, 36c, and 36d may be surrounded by the ring connectors 34 in a plan view.

The clamp 35 may be surrounded by the second connecting section 32b and the third connecting section 32c in a plan view. The clamp 35 may be surrounded by the inner side surface 32b_S of the second connecting section 32b and the inner side surface 32c_S of the third connecting section 32c.

The stiffener 54 may include a central section 54a and branch sections 54b. The branch sections 54b may be connected to the central section 54a. The branch sections 54b may be spaced apart from each other. The branch sections 54b may extend from the central section 54a. The probe connectors 52 may be disposed between the branch sections 54b. One probe connector 52 may be disposed between two adjacent branch sections 54b. The probe connectors 52 may be at the same level as the stiffener 54.

Although the central section 54a and the branch sections 54b are described separately, the central section 54a and the branch sections 54b may be connected to each other without any boundaries to form a single structure.

The branch sections 54b may each include a first section 54b1, a second section 54b2, and a third section 54b3. The first section 54b1 of the branch section 54b may be connected to the central section 54a. The third section 54b3 of the branch section 54b may be disposed between a pair of the adjacent probe connectors 52. The probe connectors 52 may be disposed on both sides of the third section 54b3 of the branch section 54b. The second section 54b2 of the branch section 54b may be disposed between the first section 54b1 and the third section 54b3 of the branch section 54b. Although the first section 54b1, the second section 54b2, and the third section 54b3 of the branch section 54b are described separately, the first section 54b1, the second section 54b2, and the third section 54b3 of the branch section 54b may be connected to each other without any boundaries to form a single structure.

The first section 54b1 of the branch section 54b may overlap the cover 55 and the first connecting section 32a in the third direction D3. The second section 54b2 and the third section 54b3 of the branch section 54b may not overlap the cover 55 in the third direction D3. The second section 54b2 of the branch section 54b may overlap the second connecting section 32b and the displacement sensor 36 in the third direction D3. The third section 54b3 of the branch section 54b may overlap the third connecting section 32c in the third direction D3. The displacement sensor 36 may not overlap the cover 55 in the third direction D3.

The distance between the first section 54b1 of the branch section 54b and the central section 54a may be less than the distance between the ring connectors 34 and the central section 54a and the distance between the probe connectors 52 and the central section 54a. The distance between the second section 54b2 of the branch section 54b and the central section 54a may be less than the distance between the ring connectors 34 and the central section 54a and the distance between the probe connectors 52 and the central section 54a. The distance between the first section 54b1 of the branch section 54b and the central section 54a may be less than the distance between the second section 54b2 of the branch section 54b and the central section 54a. The distance between the second section 54b2 of the branch section 54b and the central section 54a may be less than the distance between the third section 54b3 of the branch section 54b and the central section 54a.

The horizontal width (or diameter) of the central section 54a may be less than the horizontal width (or diameter) of the cover 55. The ring connectors 34 may be connected to the lower surface 32c_L of the third connecting section 32c. The ring connectors 34 may be in contact with the lower surface 32c_L of the third connecting section 32c. The probe connector 52 may include lines (or contacts or pins) 52a. The lines 52a include conductive materials.

The displacement sensor 36 may identify the vertical position of the probe card 50. For example, the displacement sensor 36 may measure the distance between the branch section 54b of the stiffener 54 and the displacement sensor 36. The displacement sensor 36 may measure a distance L2 in the third direction D3 between a lowermost portion 36_L of the displacement sensor 36 and the upper surface 54_U of the stiffener 54. The displacement sensor 36 may measure the distance in the third direction D3 between the lowermost portion 36_L of the displacement sensor 36 and the upper surface of the branch section 54b of the stiffener 54. The upper surface of the branch section 54b of the stiffener 54 may be a portion of the upper surface 54_U of the stiffener 54.

The branch sections 54b may include a first branch section 54ba, a second branch section 54bb, a third branch section 54bc, and a fourth branch section 54bd. The first displacement sensor 36a may measure the distance between the first branch section 54ba and the first displacement sensor 36a. The second displacement sensor 36b may measure the distance between the second branch section 54bb and the second displacement sensor 36b. The third displacement sensor 36c may measure the distance between the third branch section 54bc and the third displacement sensor 36c. The fourth displacement sensor 36d may measure the distance between the fourth branch section 54bd and the fourth displacement sensor 36d. The first to fourth branch sections 54ba, 54bb, 54bc, and 54bd may be spaced apart from each other.

The first displacement sensor 36a may overlap the first branch section 54ba in the third direction D3. The second displacement sensor 36b may overlap the second branch section 54bb in the third direction D3. The third displacement sensor 36c may overlap the third branch section 54bc in the third direction D3. The fourth displacement sensor 36d may overlap the fourth branch section 54bd in the third direction D3. In FIG. 3, the positions of the first to fourth displacement sensors 36a, 36b, 36c, and 36d are shown as dashed lines.

The displacement sensor 36 may include components for measuring a distance. For example, the displacement sensor 36 may include a sensor head, an amplifier unit, a communication unit, and a bracket. In some embodiments, the lowermost portion 36_L of the displacement sensor 36 may represent the lowermost portion of the sensor head. The displacement sensor 36 may measure the distance in the third direction D3 between the lowermost portion of the sensor head and the upper surface 54_U of the stiffener 54. The bracket may fix the displacement sensor 36 to the connecting ring 32. The displacement sensor 36 may be, for example, a laser displacement sensor or a camera-based optical sensor. A laser displacement sensor typically operates by emitting a laser beam onto the target surface and measuring the reflected beam, enabling high-resolution, non-contact distance measurements.

The tester 10 may run software for controlling the operation of the displacement sensor 36. The tester 10 may include a controller for running the software. The controller may be a computer or a processor, such as a DSP, an FPGA, a CPU, a GPU, or a microprocessor. The controller may be a semiconductor chip. The controller may be configured to determine whether the probe card 50 is decoupled from the ring connector 34.

The displacement sensor 36 may have a measurement range of, for example, about 1 mm and a resolution of, for example, about 0.1 μm. For example, the displacement sensor 36 may be capable of measuring distances in a predetermined range (e.g., 1 mm±20%), with a predetermined resolution (e.g., 0.1 mm±10%). The range and the resolution may be determined in consideration of the dimensions of the components of the test apparatus (e.g., the connecting ring 32, the first fixing part 33, the ring connector 34, the clamp 35, the second fixing part 42, the probe connector 52 and/or the stiffener 54).

FIG. 6 is a diagram showing the probe connector 52 and the ring connector 34. FIG. 6 is a cross-sectional view that illustrates in detail how the ring connector 34 and the probe connector 52 are mechanically and electrically coupled.

Referring to FIG. 6, the ring connector 34 may include coupling portions 34a. The coupling portions 34a are movable. The coupling portions 34a may be connected to the lines 52a of the probe connector 52 (see FIG. 5). The coupling portions 34a may be in contact with the lines 52a of the probe connector 52. The coupling portions 34a may include (or constitute a part of) an electrical path through which an electrical signal passes. The coupling portions 34a are connected to the lines 52a of the probe connector 52, and thus, the ring connector 34 may be electrically connected to the probe connector 52.

The coupling portions 34a may press the probe connector 52. The coupling portions 34a press the probe connector 52, and thus, the probe connector 52 may be coupled to the ring connector 34. For example, the coupling portions 34a and the probe connector 52 may be mechanically and electrically engaged with each other by applying a mechanical force. The coupling portions 34a may be conductive contacts that are spring-loaded or otherwise movable to contact and apply a lateral force to opposite sides of the probe connector 52 when engaged. For ease of understanding the drawing, the coupling portions 34a are not shown in FIG. 5, and FIG. 6 depicts only a single pin 52a. However, it would be apparent to those skilled in the art, from these figures and the accompanying description, that multiple pins 52a shown in FIG. 5 may be mechanically and electrically coupled to the ring connector 34 via multiple pairs of coupling portions 34a. Each of the multiple pins 52a and a corresponding pair of the coupling portions 34a may be configured to allow the transmission and reception of a distinct electrical signal (or voltage) between the test plate 31 and probe card 50.

The test apparatus according to some embodiments includes the displacement sensors 36, and thus, it may be determined whether the probe connector 52 is coupled to or decoupled from the ring connector 34 by using the displacement sensors 36. For example, by using the displacement sensors 36, the tester 10 may determine whether the probe connector 52 is fully coupled to the ring connector 34, decoupled from it, or in a partially connected state (or in an incomplete decoupling state, e.g., to have a relatively weak, a partial, or an insecure mechanical engagement). Accordingly, it is possible to prevent the probe card 50 from being damaged by rotation of the rotating arm 22 in a state in which the probe connector 52 is coupled to the ring connector 34. For example, it is possible to prevent the probe card 50 from being damaged by rotation of the rotating arm 22 while the probe connector 52 is still coupled to the ring connector or is in a partially connected state.

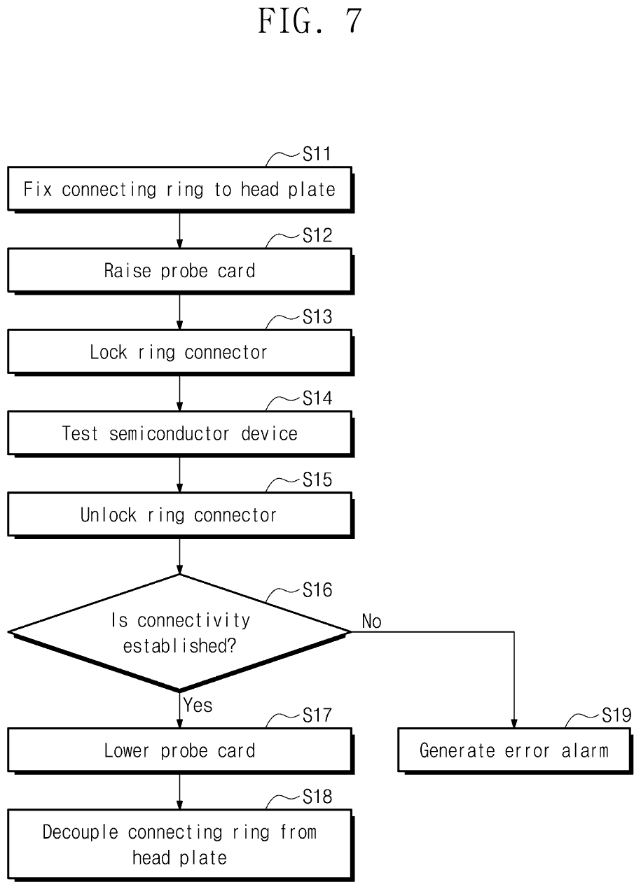

FIG. 7 is a flowchart illustrating a semiconductor device testing method according to some embodiments. FIGS. 8, 9, and 10 are diagrams illustrating the semiconductor device testing method according to some embodiments.

Referring to FIGS. 1, 2, 3, 4, 5, 6 and 7, the semiconductor device testing method includes fixing the connecting ring 32 to the head plate 41 (S11), raising the probe card 50 (S12), locking the ring connector 34 (S13), testing the semiconductor device (S14), unlocking the ring connector 34 (S15), determining by the displacement sensor 36 whether the probe connector 52 is coupled to or decouples from the ring connector 34 (S16), lowering the probe card 50 (S17), decoupling the connecting ring 32 from the head plate 41 (S18), and generating an error alarm (S19).

The fixing of the connecting ring 32 to the head plate 41 (S11) may include rotating the rotating arm 22 to place the first fixing part 33 on the head plate 41, and coupling the first fixing part 33 to the second fixing part 42. The first fixing part 33 may be coupled to the second fixing part 42 by, for example, rotational movement of the first fixing part 33 and/or the second fixing part 42.

The raising of the probe card 50 (S12) may include raising the card holder 60. The card holder 60 may move in the third direction D3.

The locking of the ring connector 34 (S13) may include pressing the probe connector 52 against the coupling portions 34a of the ring connector 34. The coupling portions 34a of the ring connector 34 press the probe connector 52, and the probe connector 52 may be coupled to the ring connector 34. Accordingly, the probe connector 52 may be electrically connected to the ring connector 34.

After locking of the ring connector 34, the displacement sensor 36 may identify the vertical position of the probe card 50. For example, the displacement sensor 36 may measure the distance between the displacement sensor 36 and the probe card 50. The displacement sensor 36 may measure the distance L2 between the lowermost portion 36_L of the displacement sensor 36 and the upper surface 54_U of the stiffener 54. It may be determined whether the distance L2 between the lowermost portion 36_L of the displacement sensor 36 and the upper surface 54_U of the stiffener 54 is less than or equal to a reference value. For example, the reference value may be about 1 mm or less. For example, the reference value may be 1 mm+10% or less. The displacement sensor 36 may transmit a signal indicating that the probe connector 52 is fully coupled to the ring connector 34 (e.g., “CONNECTED”) to the tester 10 when the distance L2 between the lowermost portion 36_L of the displacement sensor 36 and the upper surface 54_U of the stiffener 54 is less than or equal to the reference value.

In an embodiment, the displacement sensor 36 may measure (or calculate by using the distance L2) the distance L1 in a third direction D3 between the lower surface 32b_L of the second connecting section 32b and an upper surface 54_U of the stiffener 54. The distance L1 may be compared to another reference value to transmit a signal “CONNECTED”.

The testing of the semiconductor device (S14) may include testing the semiconductor device by using the probe card 50. The testing of the semiconductor device (S14) may include transmitting an electrical signal to the semiconductor device via the probe pins 53 and receiving the electrical signal from the semiconductor device via the probe pins 53.

Referring to FIGS. 7 and 8, when the test of the semiconductor device is completed, the ring connector 34 may be unlocked (S15). The unlocking of the ring connector 34 (S15) may include separating the coupling portions 34a of the ring connector 34 from the probe connector 52. The coupling portions 34a of the ring connector 34 are spaced apart from the probe connector 52, and thus, the probe connector 52 may be decoupled from the ring connector 34.

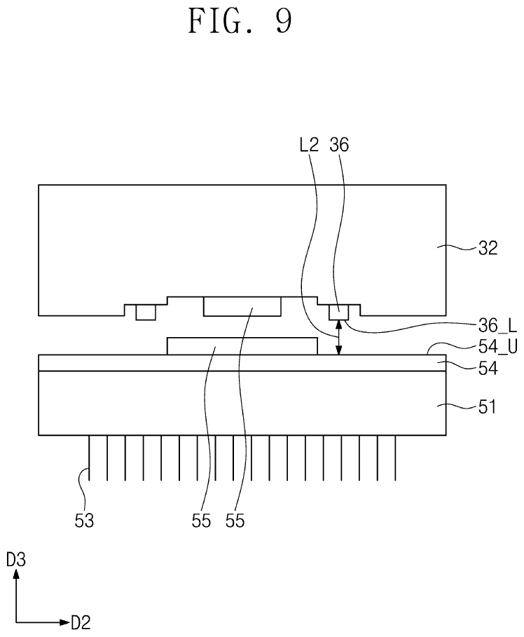

Referring to FIGS. 7 and 9, the probe connector 52 and the ring connector 34 may be in three states such as fully decoupled, fully decoupled, partially coupled/decoupled and fully coupled, and it may be determined whether the probe connector 52 is coupled to or decoupled from the ring connector 34 (S16). “Coupled” may mean fully/properly coupled. “Decoupled” may mean either partially decoupled (and thus partially connected) or fully decoupled. When the probe connector 52 is decoupled from the ring connector 34, the distance L2 between the lowermost portion 36_L of the displacement sensor 36 and the upper surface 54_U of the stiffener 54 may increase. For example, the distance L2 between the lowermost portion 36_L of the displacement sensor 36 and the upper surface 54_U of the stiffener 54 may increase due to gravity. The displacement sensor 36 may identify the vertical position of the probe card 50. For example, the displacement sensor 36 may measure the distance between the displacement sensor 36 and the probe card 50. The displacement sensor 36 may measure the distance L2 between the lowermost portion 36_L of the displacement sensor 36 and the upper surface 54_U of the stiffener 54.

It may be determined whether the distance L2 between the lowermost portion 36_L of the displacement sensor 36 and the upper surface 54_U of the stiffener 54 is greater than the reference value. The displacement sensor 36 may transmit a signal “ABNORMAL” to the tester 10 when the distance L2 between the lowermost portion 36_L of the displacement sensor 36 and the upper surface 54_U of the stiffener 54 is greater than the reference value. For example, by using the displacement sensors 36 and the reference value, the tester 10 may determine whether the probe connector 52 is fully decoupled from the ring connector 34.

The determining of whether the probe connector 52 is coupled to or decoupled from the ring connector 34 (S16) may include determining whether each pair of a probe connector 52 is coupled to or decoupled from a corresponding ring connector 34 by using the first to fourth displacement sensors 36a, 36b, 36c, and 36d (FIG. 2). For example, the pairs of the probe connector 52 and the corresponding ring connector 34 individually may either be connected state or disconnected—e.g., the distance L2 is less than or greater than the reference value. Based on whether the entire probe connectors are fully coupled, partially coupled/decoupled, or fully decoupled.

The determining of whether the probe connector 52 is coupled to or decoupled from the ring connector 34 (S16) may include measuring the distance in the third direction D3 between the first displacement sensor 36a and the first branch section 54ba of the stiffener 54 of the probe card 50, measuring the distance in the third direction D3 between the second displacement sensor 36b and the second branch section 54bb of the stiffener 54 of the probe card 50, measuring the distance in the third direction D3 between the third displacement sensor 36c and the third branch section 54bc of the stiffener 54 of the probe card 50, and measuring the distance in the third direction D3 between the fourth displacement sensor 36d and the fourth branch section 54bd of the stiffener 54 of the probe card 50.

The determining of whether the probe connector 52 is coupled to or decoupled from the ring connector 34 (S16) may include determining whether the distance in the third direction D3 between the first displacement sensor 36a and the first branch section 54ba of the stiffener 54 of the probe card 50 exceeds the reference value, determining whether the distance in the third direction D3 between the second displacement sensor 36b and the second branch section 54bb of the stiffener 54 of the probe card 50 exceeds the reference value, determining whether the distance in the third direction D3 between the third displacement sensor 36c and the third branch section 54bc of the stiffener 54 of the probe card 50 exceeds the reference value, and determining whether the distance in the third direction D3 between the fourth displacement sensor 36d and the fourth branch section 54bd of the stiffener 54 of the probe card 50 exceeds the reference value.

In an embodiment, the displacement sensor 36 may measure (or calculate by using the distance L2) the distance L1 in a third direction D3 between the lower surface 32b_L of the second connecting section 32b and an upper surface 54_U of the stiffener 54. The distance L1 may be compared to the reference value used when comparing the distance L2 as described above.

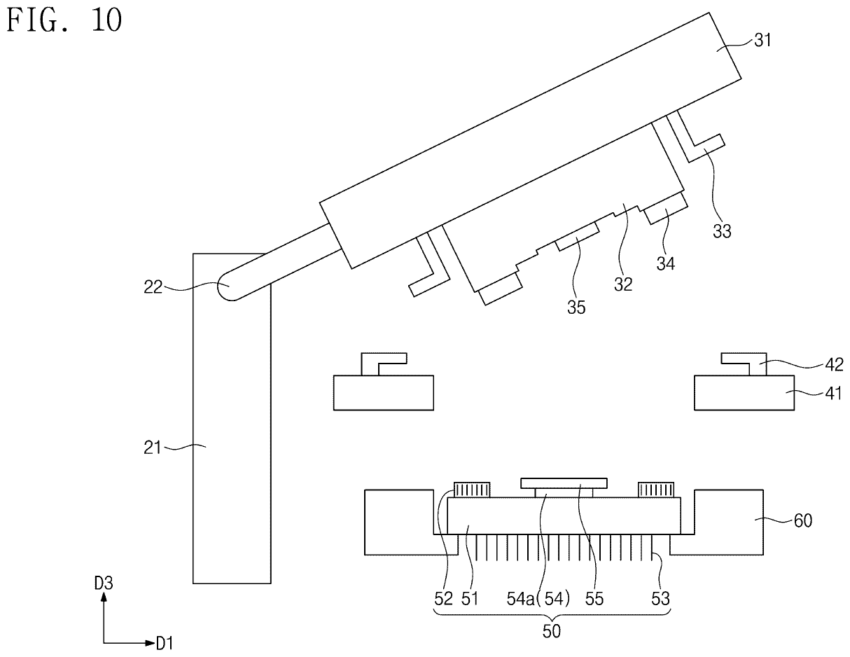

Referring to FIGS. 7 and 10, the probe card 50 may be lowered (S17) when each pair of a probe connector 52 is decoupled from a corresponding ring connector 34. The lowering of the probe card 50 (S17) may include lowering the card holder 60. The card holder 60 may move in the opposite direction to the third direction D3.

Subsequently, the connecting ring 32 may be decoupled from the head plate 41 (S18). The decoupling of the connecting ring 32 from the head plate 41 (S18) may include decoupling the first fixing part 33 from the second fixing part 42 and rotating the rotating arm 22 to separate the first fixing part 33, the test plate 31, and the connecting ring 32 from the head plate 41. The first fixing part 33 may be separated from the second fixing part 42 by, for example, rotational movement. The rotating arm 22 may, for example, rotate about 180 degrees.

Referring to FIG. 7, when each pair of a probe connector 52 is decoupled from a corresponding ring connector 34, an error alarm may be generated (S19). The error alarm may include, for example, a visual or audible alarm. For example, by using the displacement sensors 36 and the reference value, the tester 10 may determine whether the probe connector 52 is coupled to or decoupled from the ring connector 34. For example, when the distance L2 between the lowermost portion 36_L of the displacement sensor 36 and the upper surface 54_U of the stiffener 54 is less than or equal to the reference value, the tester 10 may determine whether the probe connector 52 and the ring connector 34 when the probe connector 52 is coupled from the ring connector 34.$$$

In the description above, the reference value used after the step S13 (locking of the ring connector 34) to transmit a signal “CONNECTED” is described the same as the reference value used in the operation S16 (determining whether the probe connector 52 is coupled to or decoupled from the ring connector 34). However, the invention is not limited thereto. For example, the reference value used after the step S13 to transmit a signal “CONNECTED” may be greater than the reference value used in the operation S16.

The semiconductor device testing method according to some embodiments includes measuring the distance between the probe card 50 and the displacement sensor 36, thereby preventing the rotating arm 22 from operating in a state in which the probe card 50 is connected to the connecting ring 32. This may prevent the probe card 50 from being damaged due to moving along with the connecting ring 32.

The test apparatus according to the inventive concept may include the displacement sensors, thereby preventing the test plate and the connecting ring from moving in a state in which the probe connector is coupled to the ring connector. Accordingly, damage to the probe card may be prevented.

Although the embodiments of aspects of the present invention have been described, it is understood that the present invention should not be limited to these embodiments but various changes and modifications can be made by one ordinary skilled in the art within the spirit and scope of the present invention as hereinafter claimed.

For example, in some embodiments, the probe connector 52 and the ring connector 34 may be in three states such as fully decoupled, partially coupled/decoupled, and fully coupled. In the operation S16, it may be determined whether the probe connector 52 and the ring connector 34 are in one of the three stages, based on the measured distance L2 between the lowermost portion 36_L of the displacement sensor 36 and the upper surface 54_U of the stiffener 54. Based on the determination, two different types of error alarms may be generated in the operation S19.

1. A test apparatus comprising:
a probe card;
a connecting plate spaced apart from the probe card;
a first displacement sensor connected to a lower surface of the connecting plate; and
interface connectors electrically connected to the connecting plate,
wherein the probe card comprises:
a probe plate, and
probe connectors on the probe plate.

2. The test apparatus of claim 1, wherein the probe card further comprises a stiffener on the probe plate, and
the first displacement sensor overlaps the stiffener.

3. The test apparatus of claim 2, wherein the stiffener comprises a central section and branch sections connected to the central section,
the branch sections are spaced apart from each other,
the branch sections include a first branch section, and
the first displacement sensor overlaps the first branch section.

4. The test apparatus of claim 3, further comprising a second displacement sensor,
wherein the branch sections further include a second branch section, and
wherein the second displacement sensor overlaps the second branch section.

5. The test apparatus of claim 4, wherein the first displacement sensor and the second displacement sensor are surrounded by the interface connectors in a plan view.

6. The test apparatus of claim 3, wherein the probe connectors are disposed between the branch sections.

7. The test apparatus of claim 3,
wherein each of the branch sections comprises:
a first section connected to the central section;
a second section between the interface connectors in a plan view; and
a third section between the first section and the second section, and
wherein the first displacement sensor overlaps the third section in a plan view.

8. The test apparatus of claim 7, wherein a distance between the third section and the central section is less than a distance between the interface connectors and the central section.

9. The test apparatus of claim 2, wherein the probe card further comprises a cover on the stiffener, and
the first displacement sensor does not overlap the cover in a plan view.

10. The test apparatus of claim 9, further comprising a clamp connected to the cover and the connecting plate.

11. The test apparatus of claim 1, wherein the connecting plate comprises:
a first connecting section;
a second connecting section surrounding the first connecting section; and
a third connecting section surrounding the second connecting section, and
wherein:
a level of a lower surface of the second connecting section is lower than a level of a lower surface of the first connecting section,
a level of a lower surface of the third connecting section is lower than the level of the lower surface of the second connecting section, and
the first displacement sensor is connected to the lower surface of the second connecting section.

12. The test apparatus of claim 11, wherein the interface connectors are connected to the lower surface of the third connecting section.

13. A test apparatus comprising:
a probe plate;
a stiffener on the probe plate;
a probe connector on the probe plate;
probe pins connected to the probe plate;
a connecting plate spaced apart from the stiffener; and
a displacement sensor overlapping the stiffener in a plan view,
wherein the displacement sensor is disposed between the connecting plate and the stiffener in a plan view.

14. The test apparatus of claim 13, wherein the connecting plate comprises a first connecting section and a second connecting section surrounding the first connecting section,
a level of a lower surface of the second connecting section is lower than a level of a lower surface of the first connecting section, and
the displacement sensor is connected to the lower surface of the first connecting section.

15. The test apparatus of claim 14, further comprising an interface connector configured to electrically connect the probe connector to the connecting plate,
wherein the interface connector is connected to the lower surface of the second connecting section.

16. The test apparatus of claim 13, wherein the stiffener comprises a central section and branch sections connected to the central section,
the probe connector is disposed between the branch sections in a plan view, and
the displacement sensor overlaps one of the branch sections in a plan view.

17-20. (canceled)

21. A test apparatus comprising:
a probe card including a plurality of first connectors;
a tester;
a plurality of second connectors electrically connected to the tester and configured to electrically and mechanically couple to the plurality of first connectors;
a displacement sensor configured to identify a vertical position of the probe card; and
a controller configured to determine whether the plurality of first connectors are coupled to or decoupled from the plurality of second connector by using the vertical position.

22. The test apparatus of claim 21, wherein, in a plan view, the displacement sensor is surrounded by the plurality of first connectors.

23. The test apparatus of claim 21, wherein the controller is configured to compare the vertical position with a predetermined reference value to determine whether the probe card is coupled to or decoupled from the plurality of second connectors by using the vertical position.

24. The test apparatus of claim 21, wherein the plurality of second connectors are configured to move away from the probe card.

25-26. (canceled)
